(19) United States
(12) Patent Application Publication
(10) Pub. No.: US 2026/0153737 A1
(43) Pub. Date: Jun. 4, 2026

(54) HEAD MOUNTED DISPLAY DEVICE HAVING TRANSMISSION COIL AND USER INTERACTION ESTIMATION SYSTEM COMPRISING SAME

(71) Applicant: LG ELECTRONICS INC., Seoul (KR)

(72) Inventors: Seungwoo RYU, Seoul (KR); Mansoo SIN, Seoul (KR); Kyungsoon PARK, Seoul (KR); Hyoungsik YUN, Seoul (KR)

(73) Assignee: LG ELECTRONICS INC., Seoul (KR)

(21) Appl. No.: 19/123,644

(22) PCT Filed: Oct. 28, 2022
(86) PCT No.: PCT/KR2022/016750

§ 371 Date: Apr. 23, 2025

(51) Int. Cl. H02J 50/90

(52) U.S. Cl. CPC G02B 27/017; G01R 33/0005; G01R 33/0047; G01R 33/02; G06F 3/011; G02B 2027/0178

(57) ABSTRACT

A head mounted display device according to the present specification comprises: a body part including a display unit which outputs an image; a transmission coil formed to have a circular shape, disposed above a user's head on which the body part is mounted, and having a number of turns to form a magnetic field over a three-dimensional space region about the head; and a main board operatively coupled to the transmission coil and configured to transmit a signal to the transmission coil. The three-dimensional space region where the magnetic field is formed may be determined on the basis of the intensity of the magnetic field.

### TECHNICAL FIELD

The present disclosure relates to a head-mounted display device including a transmitting coil. More particularly, the present disclosure relates to a head-mounted display device that includes a transmitting coil, and to a system for estimating user interaction, the system including the head-mounted display device.

### BACKGROUND ART

A system for estimating user interaction estimates the position and orientation of a user's motion. The system includes a transmitting device with a transmitting coil, and a receiving device with a receiving coil. It is possible to estimate the position and orientation of the user's motion using an electric-field or magnetic-field technique involving the transmitting coil and the receiving coil.

To accurately estimate the user's motion within a three-dimensional space, the transmitting coil and the receiving coil may be implemented as three-axis coils. In a three-axis to three-axis coil system between the transmitting device and the receiving device, a problem arises in that the coil structure itself is bulky. Therefore, the three-axis to three-coil system poses a problem for use in commercial wearable devices.

The transmitting device including the transmitting coil may be implemented in a head-mounted display (HMD) device worn on a user's head. The receiving device may be carried, for example, in the user's hand, or may be worn on body parts such as the wrist and/or ankle. The receiving coil of the receiving device may be formed as a three-axis coil to enclose an internal mechanical structure of the receiving device. However, in a case where the transmitting device including the transmitting coil is implemented in an HMD device, the transmitting coil cannot be formed in such a manner as to enclose the user's head. Therefore, when the transmitting device is implemented in an HMD device, the transmitting coil needs to be implemented as a single-axis coil. In a case where the transmitting coil is implemented as a single-axis coil, it is important to analyze a three-dimensional spatial region and a coverage radius along three axes, which are formed by a magnetic field generated by the transmitting coil.

In addition, in a case where the transmitting coil is placed in the HMD device, it is important to analyze the impact of an electric or magnetic field on the human body. In view of the characteristic of wearable devices that are worn on the user's body, it is necessary to consider human health issues. However, in the case of typical wearable devices, a problem arises in that it is difficult to accurately analyze the physical effects on the human body solely through the analysis of the influence of electric or magnetic fields. Therefore, it is necessary to accurately analyze the effects of electric fields or magnetic fields on the human body, with consideration of the placement structures and mechanical structures of coils and similar components included in various wearable devices.

Particularly, using the HMD device, it is necessary to analyze the minimum separation distance between the coil and the user's head, based on an appropriate level of maximum power exposure (MPE), with consideration of the impact on human health. In addition, it is necessary to ensure sufficient coverage of the magnetic field generated by the coil, based on the coil placement resulting from taking into consideration the minimum separation distance between the coil and the user's head, and on the current applied to the coil.

The human body possesses a relative permittivity significantly higher than 1, which causes it to absorb electric fields. As a result, harmful effects may occur within the body due to the absorbed electric field. Conversely, since the human body has a relative permeability of approximately 1, magnetic fields are not significantly absorbed and can pass through the human body.

In conclusion, a wearable device-based system for estimating user interaction, where a 1-axis to 3-axis coil system is implemented in both the transmitting device and the receiving device, may estimate the user's motion based on the magnetic field. In this magnetic field-based system for estimating user interaction, it is necessary to design the shape and placement structure of the transmitting coil, which results from taking into consideration a design element of a commercial wearable device. In the commercial wearable device, an MPE-based separation distance should be minimized.

### DISCLOSURE OF INVENTION

### Technical Problem

One object of the present disclosure is to provide a head-mounted display device, including a transmitting coil and, and a system for estimating user interaction, the system including the head-mounted display device.

Another object of the present disclosure is to accurately estimate a user's motion through analysis of a three-dimensional spatial region and a coverage radius along three axes, which are formed by a magnetic field generated by a transmitting coil, in a case where the transmitting coil is implemented as a single-axis coil.

A further object of the present disclosure is to analyze the minimum separation distance between a coil and a user's head, based on an appropriate level of maximum power exposure (MPE), with consideration of the impact on human health, using an HMD device.

Another object of the present disclosure is to analyze usage scenario coverage based on human body proportions, as well as an MPE-based separation distance resulting from taking into consideration human health risks in an HMD device.

Still another object of the present disclosure is to propose a coil shape and a placement structure that are capable of being implemented with the smallest coil having the smallest magnetic moment based on usage scenario coverage analysis resulting from taking into consideration human body proportions.

Yet another object of the present disclosure is to ensure sufficient coverage of a magnetic field generated by a coil, based on the coil placement resulting from taking into consideration the minimum separation distance between the coil and a user's head and on the current applied to the coil.

Another object of the present disclosure is to design the shape and placement structure of a transmitting coil, which results from taking into consideration a design element of a commercial wearable device, in a magnetic field-based system for estimating user interaction. In the commercial wearable device, an MPE-based separation distance should be minimized.

### Solution to Problem

According to one aspect of the present disclosure, there is provided a head-mounted display device including: a main body that includes a display unit outputting an image; a transmitting coil that is placed to face downward toward a user's head, on which the main body is worn, and is configured in a circular shape with a number of turns to form a magnetic field in a three-dimensional spatial region, with the user's head at the center; and a main board that is operatively coupled to the transmitting coil and is configured to transfer a signal to the transmitting coil. The three-dimensional spatial region where the magnetic field is generated is determined based on the intensity of the magnetic field.

According to an embodiment, the three-dimensional spatial region includes: a first coverage radius that is set in a vertical direction, with the user's head at the center; and a second coverage radius that is set in a horizontal direction, with the user's head at the center. The first coverage radius within which a receiver is placed in a state where the user lowers the user's hand is set to be greater than the second coverage radius within which the receiver is placed in a state where the user raises the user's hand in the horizontal direction.

According to an embodiment, the head-mounted display device may further include: a rear support section formed to enclose the rear part of the user's head; and a second transmitting coil placed on the rear support section in a manner that has a different shape than the transmitting coil. In the head-mounted display device, a first direction of a first magnetic flux generated by the transmitting coil and a second direction of a second magnetic flux generated by the second transmitting coil may be set to be within a range of −20 degrees to +20 degrees relative to a direction perpendicular to the user.

According to an embodiment, in the head-mounted display device, the transmitting coil is formed by winding a coil in a circular shape with a first radius, up to a first height in the vertical direction, so that the coil has a first number of turns.

According to an embodiment, in the head-mounted display device, the second transmitting coil may be formed by winding a coil in a circular shape with a second radius smaller than the first radius, up to a second height in the vertical direction, so that the coil has a second number of turns that is greater than the first number of turns. The second height may be set to be greater than the first height.

According to an embodiment, in the head-mounted display device, the first radius may be greater than or equal to 28 mm and less than or equal to 39 mm.

According to an embodiment, in the head-mounted display device, the first number of turns of the transmitting coil may be greater than or equal to 200 and less than or equal to 300.

According to an embodiment, in the head-mounted display device, in a case where the first radius of the transmitting coil is 28 mm and the first number of turns of the transmitting coil is 300, the distance between the lower end of the transmitting coil and the top of the head may be set to 4.5 cm or more. In a case where the second radius of the transmitting coil is 39 mm and the first number of turns of the transmitting coil is 200, the distance between the lower end of the transmitting coil and the top of the head may be set to 3.4 cm or more.

According to an embodiment, in the head-mounted display device, the transmitting coil and the second transmitting coil may be formed as single-axis coils to face downward toward the user's head so that magnetic flux is generated in a direction perpendicular to the user's head. The receiver may include a receiving coil formed as a three-axis coil to detect the position and orientation of the user's hand holding the receiver.

According to an embodiment, in the head-mounted display device, the main board may include a processor configured to estimate the position and orientation of the receiver with respect to the transmitting coil.

According to an embodiment, in the head-mounted display device, the transmitting coil and the second transmitting coil may be configured to generate magnetic fields at first and second frequencies, different from each other, and to transmit a first signal and a second signal, respectively. The processor may estimate the position and orientation of the receiver from the first signal at the first frequency, transmitted from the transmitting coil. When the position and orientation of the receiver are not estimated, the processor may estimate the position and orientation of the receiver from the second signal at the second frequency, transmitted from the second transmitting coil.

According to another aspect of the present disclosure, there is provided a system for estimating user interaction, the system including: a head-mounted display device that forms a three-dimensional spatial region of a magnetic field through at least one transmitting coil; and a receiver that includes a receiving coil that is placed within the three-dimensional spatial region and is configured to receive the magnetic field generated by the transmitting coil. The head-mounted display device includes: a main body that includes a display unit outputting an image; a transmitting coil that is placed to face downward toward a user's head, on which the main body is worn, and is configured in a circular shape with a number of turns to form a magnetic field in a three-dimensional spatial region, with the user's head at the center; and a main board that is operatively coupled to the transmitting coil and is configured to transfer a signal to the transmitting coil.

According to an embodiment, the three-dimensional spatial region where the magnetic field is generated is determined based on the intensity of the magnetic field. The three-dimensional spatial region includes a first coverage radius that is set in a vertical direction, with the user's head at the center; and a second coverage radius that is set in a horizontal direction, with the user's head at the center. The first coverage radius within which a receiver is placed in a state where the user lowers the user's hand is set to be greater than the second coverage radius within which the receiver is placed in a state where the user raises the user's hand in the horizontal direction.

According to an embodiment, in the system, the head-mounted display apparatus may further include: a rear support section formed to enclose the rear part of the user's head; and a second transmitting coil placed on the rear support section in a manner that has a different shape than the transmitting coil. A first direction of a first magnetic flux generated by the transmitting coil and a second direction of a second magnetic flux generated by the second transmitting coil may be set to be within a range of −20 degrees to +20 degrees relative to a direction perpendicular to the user.

According to an embodiment, in the system, the transmitting coil may be formed by winding a coil in a circular shape with a first radius, up to a first height in the vertical direction, so that the coil has a first number of turns. The second transmitting coil may be formed by winding a coil in a circular shape with a second radius smaller than the first radius, up to a second height in the vertical direction, so that the coil has a second number of turns that is greater than the first number of turns. The second height may be set to be greater than the first height.

According to an embodiment, in the system, the first radius may be greater than or equal to 28 mm and less than or equal to 39 mm. The first number of turns of the transmitting coil may be greater than or equal to 200 and less than or equal to 300.

According to an embodiment, in the system, in a case where the first radius of the transmitting coil is 28 mm and the first number of turns of the transmitting coil is 300, the distance between the lower end of the transmitting coil and the top of the head may be set to 4.5 cm or more. In a case where the second radius of the transmitting coil is 39 mm and the first number of turns of the transmitting coil is 200, the distance between the lower end of the transmitting coil and the top of the head may be set to 3.4 cm or more.

According to an embodiment, in the system, the transmitting coil and the second transmitting coil may be formed as single-axis coils to face downward toward the user's head so that magnetic flux is generated in a direction perpendicular to the user's head. The receiver may include a receiving coil formed as a three-axis coil to detect the position and orientation of the user's hand holding the receiver.

According to an embodiment, in the system, the receiver may further include a processor configured to estimate the position and orientation of the receiver with respect to the transmitting coil.

According to an embodiment, in the system, the transmitting coil and the second transmitting coil may be configured to generate magnetic fields at first and second frequencies, different from each other, and to transmit a first signal and a second signal, respectively. The processor may estimate the position and orientation of the receiver from the first signal at the first frequency, transmitted from the transmitting coil. When the position and orientation of the receiver are not estimated, the processor may estimate the position and orientation of the receiver from the second signal at the second frequency, transmitted from the second transmitting coil.

### Advantageous Effects of Invention

According to the present disclosure, a transmitting device including a transmitting coil may be implemented in a head-mounted display device. In addition, a system for estimating user interaction can be provided that includes the transmitting device, including the transmitting coil, and a receiving device, including a receiving coil.

According to the present disclosure, in a case where the transmitting coil is implemented as a single-axis coil, it is possible to design the shape and placement structure of the transmitting coil, which result from taking into consideration a three-dimensional spatial area and a coverage radius along three axes, which are formed by a magnetic field generated by the transmitting coil. It is possible to accurately estimate a user's motion by analyzing the three-dimensional spatial region and the coverage radius along the three axes, which is formed by the magnetic field resulting from taking into consideration the shape and placement of the transmitting coil.

According to the present disclosure, using the HMD device, it is possible to analyze the minimum separation distance between the coil and the user's head, based on an appropriate level of maximum power exposure (MPE), with consideration of the impact on human health. Particularly, it is possible to accurately estimate the user's motion through the analysis of the minimum separation distance between the coil and the user's head, based on the MPE of the magnetic field generated according to the shape and placement structure of the transmitting coil.

According to the present disclosure, it is possible to analyze usage scenario coverage based on human body proportions, as well as an MPE-based separation distance resulting from taking into consideration human health risks in an HMD device.

According to the present disclosure, a coil shape and a placement structure can be proposed that are capable of being implemented with the smallest coil having the smallest magnetic moment based on usage scenario coverage analysis resulting from taking into consideration human body proportions.

According to the present disclosure, sufficient coverage of a magnetic field generated by the coil can be ensured, based on the coil placement resulting from taking into consideration the minimum separation distance between the coil and a user's head and on the current applied to the coil.

According to the present disclosure, it is possible to design the shape and placement structure of the transmitting coil, which result from taking into consideration a design element of a commercial wearable device, in a magnetic field-based system for estimating user interaction. In the commercial wearable device, an MPE-based separation distance should be minimized.

Further scope of applicability of the present disclosure will become apparent from the following detailed description. However, various alterations and modifications to the present disclosure would be readily understood by a person of ordinary skill in the art without departing from the spirit and scope of the underlying technical idea of the present disclosure. The detailed description and specific embodiments, such as preferred embodiments of the disclosure, should be understood as illustrative examples only.

### BRIEF DESCRIPTION OF DRAWINGS

FIG. 1 is a basic block diagram illustrating a system for user interaction according to one embodiment.

FIG. 2 is a view illustrating a configuration in which a transmitting coil and receivers are placed relative to the user's body and receivers are placed on the user's body, in association with respect to the system for user interaction in FIG. 1.

FIGS. 3 and 4 are views that, respectively, illustrate the configurations of transmitting and receiving devices according to the present disclosure, which estimate user interaction based on wireless power.

FIG. 5 is a block diagram illustrating a wireless power transmitting device configured to have one or more transmitting coils that are usable in embodiments disclosed in the present specification.

FIG. 6 is a view illustrating the configurations of a transmitting coil, a receiving coil, and sensors in a system for estimating user interaction according to embodiments of the present disclosure.

FIGS. 7A and 7B are views, each illustrating a coverage region that results from taking into consideration the user's hand motion for estimating the user interaction according to the present disclosure.

FIG. 8 is a view illustrating a structure in which the transmitting coil of the transmitting device can be placed, assuming a state in which the user is wearing a head-mounted display (HMD).

FIGS. 9A and 9B are views, each illustrating the configuration of the head-mounted display device according to the present disclosure, which includes the transmitting coil.

FIGS. 10A and 10B are views, each illustrating the detailed structure of a head-mounted display device according to an embodiment.

FIG. 11 is a view illustrating a structure in which a plurality of transmitting coils are placed at different positions on the user's head.

FIG. 12 is a view illustrating a comparison between three-dimensional spatial regions in which a magnetic field is generated depending on the position of the transmitting coil.

FIG. 13 is a set of views illustrating the coverage radii of the magnetic fields generated by the transmitting coil in Table 2, shown in the form of different cross-sectional views.

FIG. 14 is a block diagram illustrating the system for estimating user interaction according to the present disclosure.

### MODE FOR THE INVENTION

The technology disclosed in the present specification applies to wireless power transmission. However, the technology disclosed in the present specification is not limited thereto and may also apply to all systems, methods, and devices to which the underlying technical idea of the technology is applicable. Examples include power transmission systems and methods, wireless charging circuits and methods, and other methods and devices that utilize wirelessly transmitted power.

It is noted that technical terms used in the present specification are only for describing specific embodiments and are not intended to impose any limitation on the scope of the present disclosure. In addition, the technical terms used in the present specification should be construed in such a manner that they are usually understood by a person of ordinary skill in the art that the present disclosure pertains to, unless otherwise specifically defined herein. These technical terms should not be construed either too broadly or too narrowly. In addition, when the technical terms used in the present specification are ones that do not precisely express the underlying technical idea of the present disclosure, they should instead be interpreted as technical terms that would be fully understood by a person of ordinary skill in the art. In addition, general terms used in the present specification should be construed according to their dictionary definitions or understood within the context of the present specification, and should not be construed in an excessively narrow sense.

In addition, the term used in the present specification, although expressed in the singular, is construed to have its plural form as well unless the context clearly indicates otherwise. Throughout the present specification, the terms such as “is configured to include” or “includes” should not be construed as requiring all constituent elements or all steps described herein. Rather, these terms should be construed to allow for the omission of one or more elements or steps, as well as the inclusion of one or more additional elements or steps.

In addition, for descriptive convenience, the terms ‘module’ and ‘unit’ are interchangeably used in the present specification to refer to constituent elements, without implying any difference in meaning or interpretation.

In addition, the terms that indicate ordinal numbers in the present specification, such as ‘first,’ ‘second,’ and so forth, are used to describe various constituent elements for purposes of distinction without imposing any limitation on them. These terms are used solely to distinguish one element from another. For example, a first constituent element may be referred to as a second constituent element without departing from the scope of claims. Similarly, the second constituent element may be referred to as the first constituent element.

Preferred embodiments according to the present disclosure are described in detail below with reference to the accompanying drawings. For clarity, like constituent elements are designated the same reference numerals, and repetitive descriptions thereof are omitted.

In addition, if it is determined that a detailed description of technology known in the related art would hinder a clear understanding of the nature and gist of the present disclosure, such description is omitted. In addition, the accompanying drawings are provided solely to facilitate understanding of the underlying technical idea disclosed in the present specification. It should be noted that the accompanying drawings are not construed as imposing any limitation on the underlying technical idea.

### Definition

One-to-Many Communication Method: A method in which a single transmitter (Tx) communicates with multiple receivers (Rx).

One-way Communication: A communication method in which only a receiver transmits necessary messages only toward a transmitter.

Two-way Communication: A communication method in which a transmitter is capable of transmitting messages to a receiver and a receiver is capable of transmitting messages to a transmitter, allowing message transmission in both directions.

At this point, the terms transmitter and receiver are synonymous with a transmitting device and a receiving device, respectively. These terms may be hereinafter used interchangeably. Devices that transmit and receive electric field-based or magnetic field-based wireless power may be referred to as a wireless power transmitting device and a wireless power receiving device, respectively. The wireless power transmitting device and the wireless power receiving device may transmit and receive wireless power through a resonant technique or an inductive coupling technique.

It is possible to estimate user interaction using the wireless power through the resonant technique or the inductive coupling technique. In this regard, it is possible to estimate the user interaction through the electric field-based or magnetic field-based wireless power. To estimate the user interaction, the transmitting device and the receiving device, which transmit the wireless power, need to be worn on the user's body or carried in the user's hand.

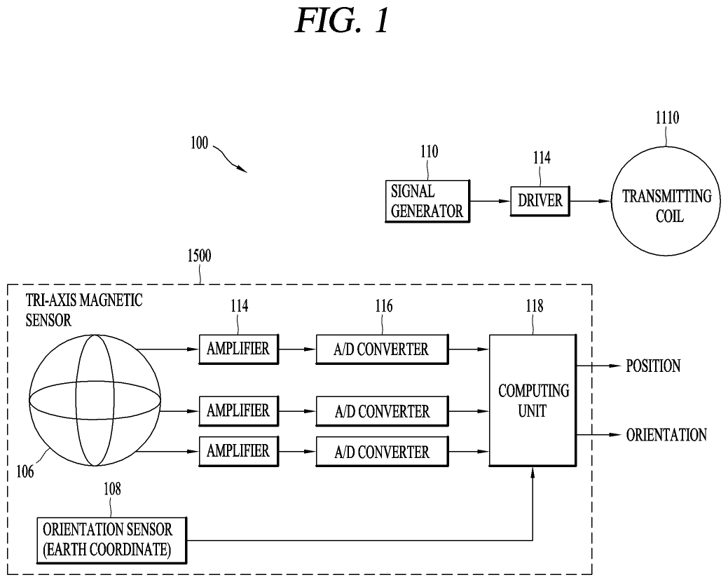

In this regard, FIG. 1 is a basic block diagram illustrating a system for user interaction according to one embodiment. In this regard, a system 100 for user interaction may also be referred to as a positioning system, as it tracks the user's motion, such as the position and orientation of the user's hand, in a state where the user wears a receiver 1500 on a part of the user's body or carries it in the user's hand.

As illustrated, the system 100 for user interaction includes a transmitter (illustrated as a transmitting coil 1110) and at least one receiver 1500. The receiver 1500 includes a tri-axis magnetic sensor 106 and an orientation sensor 108. The transmitting coil 1110 may transform an arbitrary two-dimensional shape into a three-dimensional shape, such as circular, elliptical, rectangular, square, diamond-shaped, or triangular.

A signal generator 110 and a driver 112 may be included to generate a waveform, drive the transmitting coil 1110, and thus transmit a periodic beacon signal at a fixed frequency. Any periodic signals may be used, but sine wave signals are preferred as they are most effective in simplifying the design of transmitters and receivers. The transmitting coil 1110 will generate a spatial magnetic field whose field strength and direction depend on the position in space. An amplifier 112 and an A/D converter 116, as illustrated, may be operatively connected to amplify the output of the magnetic sensor 106 and convert the amplified output into a digital form suitable for input into a computing unit 118. The computing unit 118 may further receive an orientation, which is output from the sensor 108.

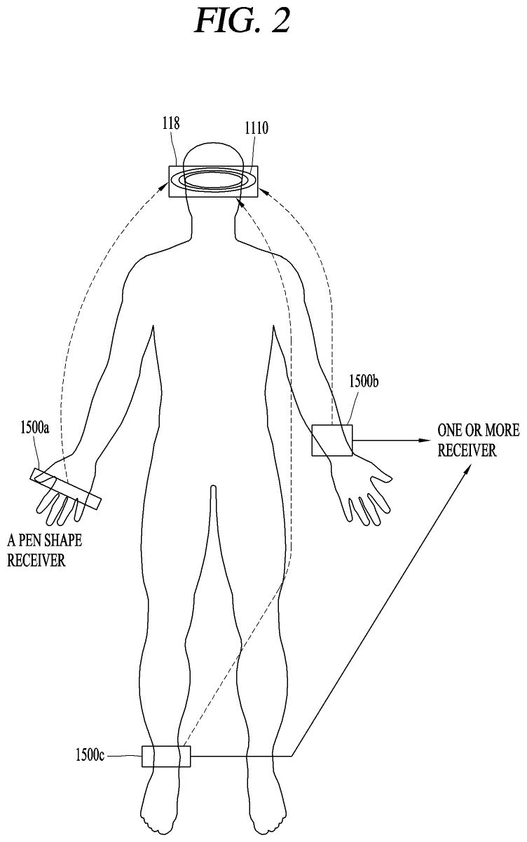

FIG. 2 is a view illustrating a configuration in which the transmitting coil are placed relative to the user's body and the receivers are on the user's body, in association with the system for user interaction in FIG. 1. As illustrated in FIG. 2, the transmitting coil 1110 and the computing device 118 may be integrated into a mobile wearable computing device (for example, a device wearable on the user's head). The mobile wearable computing device may be a head-mounted display (HMD) device, but it is not limited thereto.

Receivers 1500a, 1500b, and 1500c (as well as the magnetic sensor 106 and the orientation sensor 108 of FIG. 1) that track the user's motion may be placed on the wrist, arm, finger, ankle, or other parts, and a pen-shaped tracking receiver that may be controlled by hand may also be used. For example, the receiver 1500 may be worn on the user's left hand, right hand, and ankle. Accordingly, in order to distinguish one or more receivers 1500a, 1500b, and 1500c worn on the user's left hand, right hand, and ankle, they may be referred to as the first, second, and third receivers, respectively. One or more receivers 1500a, 1500b, and 1500c may operate simultaneously and independently to search for their positions and orientations using the same beacon signal from the transmitting coil 1110. One or more receivers 1500a, 1500b, and 1500c may transfer the measured data or estimated position/orientation data to the mobile wearable computing device through wired or wireless channels.

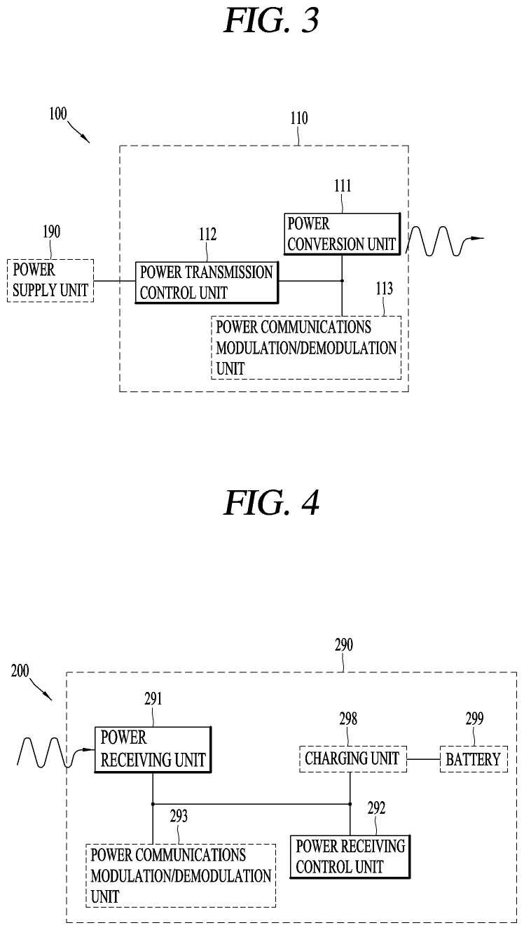

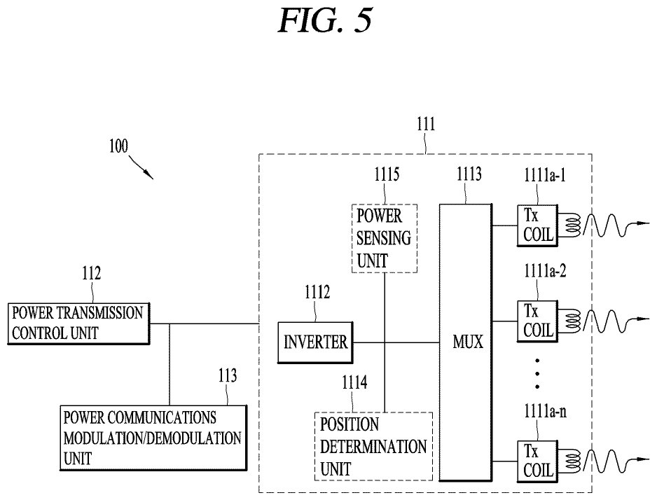

A device for transmitting wireless power and a device for receiving wireless power, which respectively transmit and receive wireless power in a system for estimating user interaction according to the present disclosure, are described below. In this regard, FIGS. 3 and 4 are views that, respectively, illustrate the configurations of the transmitting and receiving devices according to the present disclosure, which estimate the user interaction based on wireless power.

With reference to FIG. 3, a wireless power transmitting device 100 is configured to include a power transmission unit 110. The power transmission unit 110 may be configured to include a power conversion unit 111 and a power transmission control unit 112.

The power conversion unit 111 converts the power supplied from a transmission-side power supply unit 190 into a wireless power signal and transfers the resulting wireless power signal to a wireless power receiving device 200. The wireless power signal transferred by the power conversion unit 111 is formed in the shape of a magnetic field or an electromagnetic field with oscillatory characteristics. To this end, the power conversion unit 111 may be configured to include a coil from which the wireless power signal is generated.

The power conversion unit 111 may include a constituent element for forming the shape of the wireless power signal, which varies depending on each power transfer technique. For example, the power conversion unit 111 may be configured to include a primary coil that generates a varying magnetic field to induce current in a secondary coil of the wireless power receiving device 200 according to the inductive coupling technique. In addition, the power conversion unit 111 may be configured to include a coil (or antenna) that generates a magnetic field with a specific resonant frequency to generate a resonance phenomenon in the wireless power receiving device 200 according to a resonant coupling technique.

In addition, the power conversion unit 111 may transfer power using one or both of the inductive coupling and resonant coupling techniques described above.

The power conversion unit 111 may be configured to further include a circuit that may adjust characteristics, such as frequency, which is used to form the wireless power signal, and voltage and current, which are applied to form the wireless power signal.

The power transmission control unit 112 controls each component included in the power transmission unit 110. The power transmission control unit 112 may be implemented in such a manner as to be integrated with another control unit (not illustrated) that controls a wireless power supply device 100.

The areas that a wireless power signal may reach may be divided into two categories. First, an active area refers to an area through which a wireless power signal, transferring power to the wireless power receiving device 200, passes. Next, a detection area (semi-active area) refers to an area of interest where the wireless power transmitting device 100 may detect the presence of the wireless power receiving device 200. At this point, the power transmission control unit 112 may detect whether the wireless power receiving device 200 is placed in or removed from the active area or the detection area. Specifically, the power transmission control unit 112 may detect whether the wireless power receiving device 200 is placed in the active area or the detection area using a wireless power signal formed by the power conversion unit 111 or through a separately provided sensor. For example, the power transmission control unit 112 may detect the presence of the wireless power receiving device 200 by monitoring whether the characteristics of the power for forming the wireless power signal of the power conversion unit 111 change due to the influence of the wireless power receiving device 200 present in the detection area. However, the active area and the detection area may vary depending on a wireless power transfer technique, such as the inductive coupling technique or the resonant coupling technique.

The power transmission control unit 112 may perform the process of identifying the wireless power receiving device 200 according to the result of detecting the presence of the wireless power receiving device 200, or determine whether to initiate wireless power transmission.

In addition, the power transmission control unit 112 may determine one or more characteristics of the power conversion unit 111, such as frequency, voltage, and current, which serve to form the wireless power signal. The determination of the characteristics may be made based on the conditions on the side of the wireless power transmitting device 100 or the conditions on the side of the wireless power receiving device 200.

The power transmission control unit 112 may receive a power control message from the wireless power receiving device 200. The power transmission control unit 112 may determine one or more characteristics of the power conversion unit 111, such as the frequency, voltage, and current, based on the received power control message, and furthermore, may perform other control operations based on the power control message.

For example, the power transmission control unit 112 may determine one or more characteristics, such as frequency, current, or voltage, which are used to form the wireless power signal according to the power control message that includes one or more of the following: information on the amount of rectified power, charging state information, or identification information for the wireless power receiving device 200.

In addition, as additional control operations that use the power control message, the wireless power transmitting device 100 may perform general control operations related to wireless power transfer based on the power control message. For example, the wireless power transmitting device 100 may receive information to be output audibly or visually related to the wireless power receiving device 200 through the power control message or may receive information necessary for inter-device authentication and similar processes.

With reference to FIG. 4, the wireless power receiving device 200 is configured to include a power supply unit 290. The power supply unit 290 provides power necessary to operate the wireless power receiving device 200. The power supply unit 290 may be configured to include a power receiving unit 291 and a power receiving control unit 292.

The power receiving unit 291 receives power wirelessly transferred from the wireless power transmitting device 100.

The power receiving unit 291 may include a constituent element necessary to receive the wireless power signal according to a wireless power transfer technique. In addition, the power receiving unit 291 may receive power in accordance with one or more wireless power transfer techniques. In this case, the power receiving unit 291 may include different constituent elements necessary for each wireless power transfer techniques.

First, the power receiving unit 291 may be configured to include a coil for receiving a wireless power signal transferred in the shape of a magnetic or electromagnetic field with oscillatory characteristics.

For example, the power receiving unit 291 may include a secondary coil in which current is induced by a varying magnetic field. The secondary coil serves as a constituent element in accordance with the inductive coupling technique. In addition, the power receiving unit 291 may include a coil and a resonant circuit in both of which a resonance phenomenon occurs due to a magnetic field with a specific resonant frequency. The coil and the resonant circuit serve as constituent elements in accordance with the resonant coupling technique.

However, in a case where the power receiving unit 291 receives power in accordance with one or more wireless power transfer techniques, the power receiving unit 291 may be implemented in such a manner as to receive power using one coil or to receive power using coils formed differently in accordance with the power transfer techniques.

The constituent components included in the power receiving unit 291 may be configured in accordance with the inductive coupling technique or the resonant coupling technique.

The power receiving unit 291 may further include a rectifying circuit (rectifier) and a smoothing circuit (regulator) for converting the wireless power signal into direct current. In addition, the power receiving unit 291 may further include a circuit that prevents overvoltage or overcurrent from occurring due to the received power signal.

The power receiving control unit 292 controls each constituent component included in the power supply unit 290.

Specifically, the power receiving control unit 292 may transfer the power control message to the wireless power transmitting device 100. The power control message may instruct the wireless power transmitting device 100 to initiate or terminate the transfer of the wireless power signal. In addition, the power control message may instruct the wireless power transmitting device 100 to adjust the characteristics of the wireless power signal.

In order to transmit the power control message, the power receiving control unit 292 may use at least one of the following: a method of transmission through the wireless power signal or a method of transmission through other user data.

In order to transmit the power control message, the wireless power receiving device 200 may be configured to further include a power communications modulation/demodulation unit 293 that is electrically connected to the power receiving unit 291. The power communications modulation/demodulation unit 293, like in the case of the wireless power transmitting device 100 described above, may be used to transmit the power control message through the wireless power signal. The power communications modulation/demodulation unit 293 may be used as a means to adjust current and/or voltage flowing through the power conversion unit 111 of the wireless power transmitting device 100. A method that a power communications modulation/demodulation unit 113 on the side of the wireless power transmitting device 100 and the power communications modulation/demodulation unit 293 on the side of the wireless power receiving device 200 use to transmit and receive the power control messages through the wireless power signal is described below.

The wireless power signal formed by the power conversion unit 111 is received by the power receiving unit 291. At this point, the power receiving control unit 292 controls power communications modulation/demodulation unit 293 on the side of the wireless power receiving device 200 so that it modulates the wireless power signal. For example, the power receiving control unit 292 may perform a modulation process so that the amount of power received from the wireless power signal changes accordingly by changing the reactance of the power communications modulation/demodulation unit 293 connected to the power receiving unit 291. The change in the amount of power received from the aforementioned wireless power signal results in changes in the current and/or voltage of the power conversion unit 111 that forms the wireless power signal. At this point, the power communications modulation/demodulation unit 113 on the side of the wireless power transmitting device 100 detects the changes in the current and/or voltage of the power conversion unit 111 and performs a demodulation process.

That is, the power receiving control unit 292 generates a packet that includes the power control message intended to be transferred to the wireless power transmitting device 100 and modulates the wireless power signal so that the packet is contained in the wireless power signal. The power transmission control unit 112 may decode the packet based on the results of the demodulation process by the power communications modulation/demodulation unit 113, thereby acquiring the power control message contained within the packet.

Furthermore, in some embodiments, the power receiving control unit 292 may transmit user data containing the power control message through a communication means (not illustrated) included in the wireless power receiving device 200, thereby transmitting the power control message to the wireless power transmitting device 100.

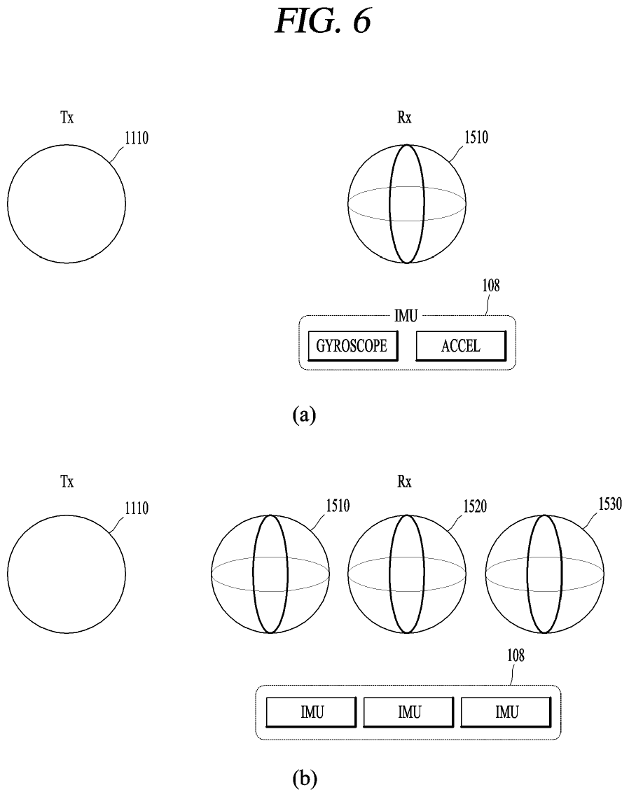

Regarding the estimation of the user interaction through the wireless power according to the present disclosure, the transmitting device may include two or more transmitting coils. In this regard, FIG. 5 is a block diagram illustrating the wireless power transmitting device configured to have one or more transmitting coils that are usable in embodiments disclosed in the present specification.

With reference to FIG. 5, the power conversion unit 111 of the wireless power transmitting device 100 according to the embodiments disclosed in the present specification may be configured with one or more transmitting coils 1111a-1 to 1111a-n. The one or more transmitting coils 1111a-1 to 1111a-n may form an array of partly overlapping primary coils. The active area may be defined by one or several of the transmitting coils.

The one or more transmitting coils 1111a-1 to 1111a-n may be mounted on the bottom of the interface surface. In addition, the power conversion unit 111 may further include a multiplexer 1113 that establishes and releases the connection of some of the coils among the one or more transmitting coils 1111a-1 to 1111a-n.

When the position of the wireless power receiving device 200 mounted on the top of the interface surface is detected, the power transmission control unit 112 may control the multiplexer 1113 so that transmitting coils that may have an inductive coupling relationship with a receiving coil 2911a of the wireless power receiving device 200, among the one or more transmitting coils 1111a-1 to 1111a-n, may be connected with consideration of the detected position of the wireless power receiving device 200.

To this end, the power transmission control unit 112 may acquire the positional information of the wireless power receiving device 200. For example, the power transmission control unit 112 may acquire the position of the wireless power receiving device 200 on the top of the interface surface through the position detection unit (not illustrated) provided in the wireless power transmitting device 100. As another example, using each of the one or more transmitting coils 1111a-1 to 1111a-n, the power transmission control unit 112 may receive the power control message indicating the strength of the wireless power signal from an object on the top of the interface surface or the power control message indicating the identification information of the object. Based on the received results, the power transmission control unit 112 may determine which of the positions of the one or more transmitting coils the object is close to, thereby acquiring the positional information of the wireless power receiving device 200.

The active area, as one portion of the interface surface, may refer to a portion through which a high-efficiency magnetic field may pass when the wireless power transmitting device 100 wirelessly transfers power to the wireless power receiving device 200. At this point, a single transmitting coil or a combination of one or more transmitting coils that generates a magnetic field passing through the active area may be referred to as a primary cell. Therefore, the power transmission control unit 112 may determine the active area based on the detected position of the wireless power receiving device 200 and establish a connection with the primary cell corresponding to the active area. Thus, the power transmission control unit 112 may control the multiplexer 1113 so that the receiving coil 2911a of the wireless power receiving device 200 and coils belonging to the primary cell may have the inductive coupling relationship.

In addition, the power conversion unit 111 may further include an impedance matching unit (not illustrated) that adjusts impedance so that impedance matching unit and the connected coils form a resonant circuit.

A method of estimating user interaction through wireless power according to the present disclosure may be performed based on an electric field or a magnetic field. When estimating the user interaction through the electric field-based wireless power, the attachment of the transmitting device to the user's body may have a harmful effect on the user's body. When estimating the interaction through the magnetic field-based wireless power, the magnetic field passes through the user's body without being absorbed, resulting in a negligible effect on the human body. However, even when estimating the interaction through the magnetic field-based wireless power, a magnetic field signal needs to be formed in an area that avoids sensory organs such as the user's eyes and ears.

In order to estimate the user interactions, while the transmitting coil of the transmitting device may be configured to generate a magnetic field, the receiving coil of the receiving device is required to receive the magnetic field signal and thus estimate the user's hand position and orientation. The estimation of the user's hand position and orientation using the receiving coil in the coverage region of the magnetic field generated by the transmitting coil according to the present disclosure may be performed using a near-field-based magnetic field. The features of a method of estimating user interaction using a near-field-based magnetic field technique may be summarized by the following technical features.
a) Better Penetration Performance: The human body has a relative permittivity significantly higher than 1 and thus absorbs the electric field. The absorbed electric field may have a harmful effect on the body. Conversely, the relative permeability of the human body has a value of approximately 1. Thus, the magnetic field penetrating the body is not absorbed but passes through the body.
b) Lower Power Consumption: The coverage radius for estimating the user's hand position and orientation using the near-field-based magnetic field is limited to a specific area. Accordingly, the value of the current applied to the transmitting coil to generate the near-field-based magnetic field is also limited to a predetermined level or below. Thus, the transmitting coil has the characteristic of low power consumption.
c) No SAR (Specific Absorption Rate): As described above, while an electric field is absorbed by the human body and may have a harmful effect on the body, a magnetic field is not absorbed and passes through the body. Accordingly, in a method of estimating position and orientation using a magnetic-field-based technique, the SAR, which corresponds to the electromagnetic energy absorbed per unit mass of body tissue, has a value of almost zero.
d) Higher Security: The coverage region of the near-field-based magnetic field is limited to the area adjacent to the body. In the near field, significant signal attenuation occurs beyond a predetermined distance, thereby making it difficult to detect a signal outside the area adjacent to the user's body. For example, the signal attenuation rate of the near-field-based magnetic field may be approximately 60 dB/dec. Accordingly, security issues arising from information leakage, such as when a signal in a near-field area adjacent to the user's body is detected in other areas, do not occur.

Implementation difficulties with a user interaction method that uses a near-field-based magnetic field may be summarized as follows.
a) Narrow transmission range due to low power and small coil
b) Constraint in 3-axis DoF: In a case where a coil is implemented as a three-axis coil, the coil is required to have a spherical shape. Accordingly, a spherical coil, such as a three-axis coil, may not be suitable for placement in a head-mounted display device worn on the user's head. Particularly, the volume of a three-axis transmitting coil may significantly increase in a case where the radius of the transmitting coil and the number of turns are increased to expand the coverage region associated with a transmission range.
c) Low data rate: For example, in a case where a near-field magnetic field in the 131 KHz band is used, the bandwidth is limited, thereby reducing the transmission data rate.

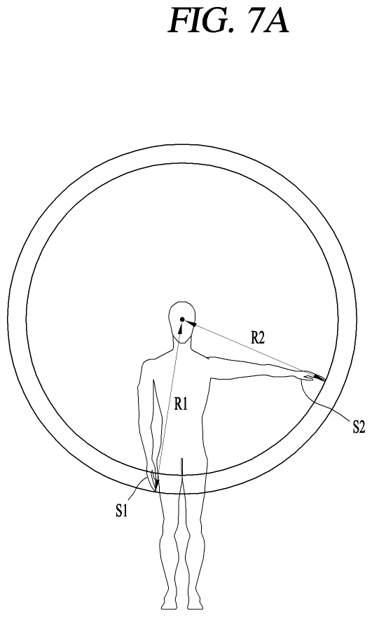

Regarding the system for user interaction, which uses the near-field-based magnetic field, FIG. 6 is a view illustrating the configurations of the transmitting coil, the receiving coil, and the sensors in the system for estimating user interaction according to embodiments of the present disclosure.

With reference to FIG. 6, the system for estimating user interaction may perform a fusion-type estimation method that uses an inertial sensor (IMU) in addition to the transmitting coil and the receiving coil. As a software architecture evolves, the fusion-type estimation method evolves in a manner that improves computation loading, measurement reliability, and accuracy. With reference to (a) of FIG. 6, in the system for estimating user interaction, the transmitting coil 1110 may be configured as a single-axis coil. For example, the transmitting coil 1110 may be formed in a circular shape on the X-Y plane so that magnetic flux is formed in the Z-axis direction corresponding to a direction perpendicular to the user. A receiving coil 1510 may be configured as a three-axis coil and may be referred to as a three-axis magnetic sensor. The receiving coil 1510 may be formed as a tri-axis circular coil arranged on different planes so that magnetic flux is generated along the X-axis, Y-axis, and Z-axis directions.

In a case where the transmitting coil is implemented as a three-axis coil, magnetic flux density may be assumed to be isotropic. In this regard, in a case where a three-axis coil is implemented in a symmetrical spherical arrangement around three axes, modeling the current flowing through the three-axis coil and the resulting generated magnetic field is possible using numerical analysis based on a point source model. Therefore, the current flowing through the three-axis coil and the resulting generated magnetic field component around three axes may be determined by mathematical equations. Particularly, a magnetic field component at a different position may be derived from a magnetic field component received at a known position using the symmetry of the magnetic field distribution. Accordingly, the technique for estimating user interaction may be simplified.

Otherwise, in a case where the transmitting coil is implemented as a single-axis coil, it is not easy to estimate the magnetic flux density and the corresponding three-dimensional spatial region along three axes. Specifically, even when the transmitting coil 1110 is implemented as a single-axis coil, the magnetic flux density and the corresponding three-dimensional spatial region of the near-field-based magnetic field along three axes are formed in a manner that varies depending on the shape, size, and height of the coil. Therefore, in a case where a single-axis coil is used, due to the asymmetry of the magnetic field distribution, a magnetic field component at a different position cannot be derived directly from a magnetic field component received at a known position.

In a case where interaction is estimated by the transmitting coil 1110 and the receiving coil 1510, an estimation error may occur due to magnetic hard/soft iron distortion and DC-DC noise from a PCB. In a case where interaction is estimated using only an acceleration sensor, an estimation error may occur due to sudden movement. In a case where interaction is estimated using only a gyroscope, an estimation error may occur due to the integration of imperfect rate measurements.

In order to minimize the occurrence of these estimation errors, the system for estimating user interaction may further include the orientation sensor 108, into which an acceleration sensor and a gyroscope are integrally formed, in addition to the transmitting coil 1110 and the receiving coil 1510. The orientation sensor 108 may be configured to sense and output the positional information and/or orientation information of the user's body part. The orientation sensor 108 may be configured as an inertial unit (IMU). The inertial sensor (IMU) may be configured to include an acceleration sensor and a gyroscope.

With reference to FIG. 2 and (b) of FIG. 6, the system for estimating user interaction may be configured to include a plurality of receiving coils. The transmitting coil 1110 may be configured as a single-axis coil. For example, the transmitting coil 1110 may be formed in a circular shape on the X-Y plane so that magnetic flux is generated in the Z-axis direction corresponding to a direction perpendicular to the user. Receiving coils 1510, 1520, and 1530 may be configured as three-axis coils and may be referred to as tri-axis magnetic sensors. The receiving coils 1510, 1520, and 1530 may be formed as three-axis circular coils, arranged on different planes so that magnetic flux is generated along the X-axis, Y-axis, and Z-axis directions. The orientation sensor 108 may be configured to sense and output the positional information and/or orientation information of the user's body part. The orientation sensor 108 may be configured to include a plurality of inertial sensors (IMUs). Similar to the illustration in (a) of FIG. 6, each inertial unit (IMU) may be configured to include an acceleration sensor and a gyroscope. The orientation sensor 108 may include a plurality of three-axis receiving coils and inertial sensors. Thus, more accurate and faster estimation of user interaction is possible.

Objects of the present disclosure, which result from taking into consideration the structures of the transmitting coil and the receiving coil, may be summarized as follows. One object of the present disclosure is to provide a head-mounted display device including a transmitting coil and a system for estimating user interaction, the system including the head-mounted display device. Another object of the present disclosure is to accurately estimate a user's motion through analysis of a three-dimensional spatial region and a coverage radius along three axes, which are formed by a magnetic field generated by a transmitting coil, in a case where the transmitting coil is implemented as a single-axis coil.

A further object of the present disclosure is to analyze the minimum separation distance between a coil and a user's head, based on an appropriate level of maximum power exposure (MPE), with consideration of the impact on human health, using an HMD device. Another object of the present disclosure is to ensure sufficient coverage of a magnetic field generated by a coil, based on the coil placement resulting from taking into consideration the minimum separation distance between the coil and a user's head and on the current applied to the coil. Still another object of the present disclosure is to design the shape and placement structure of a transmitting coil, which results from taking into consideration a design element of a commercial wearable device, in a magnetic field-based system for estimating user interaction. In the commercial wearable device, an MPE-based separation distance should be minimized.

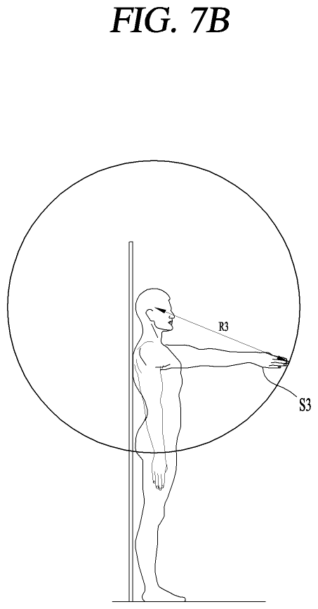

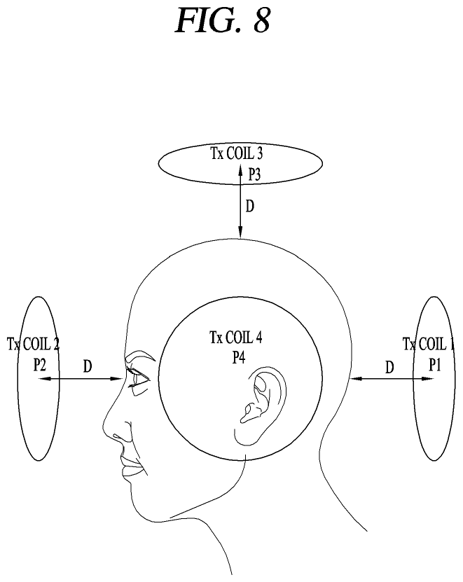

A head-mounted display device according to the present disclosure includes a transmitting coil that generates a magnetic field and is capable of being worn on the user's body. A system for estimating user interaction uses the head-mounted display device. The head-mounted display device and the system for estimating user interaction are described below. In this regard, FIGS. 7A and 7B are views, each illustrating a coverage region that results from taking into consideration the user's hand motion for estimating the user interaction according to the present disclosure. FIG. 8 is a view illustrating a structure in which the transmitting coil of the transmitting device can be placed, assuming a state in which the user is wearing the head-mounted display (HMD). With reference to FIGS. 7A and 7B, the receiving device (receiver) for estimating user interaction may be worn on the user's hand, arm, shoulder, or other body parts or may be carried in the user's hand. With reference to FIG. 8, the transmitting coils of the transmitting device (transmitter) for estimating user interaction may be placed near the front, rear, top, and sides of the head of the user wearing the HMD device.

With reference to FIGS. 2 and 7A, in a first state S1, where the user lowers the user's hand, a first coverage radius R1, which is a first distance between the HMD, which is a transmitting device, and a controller, which is a receiver, may be set to reach its maximum distance. With reference to FIGS. 2 and 7B, in a third state S3, where the user extends the user's hand forward, a third coverage radius R3, which is a third distance between the HMD, which is a transmitting device, and the controller, which is a receiver, may be set to reach its minimum distance. With reference to FIGS. 2 and 7A, in a second state S2, where the user raises the user's arm parallel to the ground, a second distance between the HMD, which is a transmitting device, and the controller, which is a receiver, may be shorter than the first distance and longer than the third distance. In other words, a second coverage radius R2 may be set to be shorter than the first coverage radius R1 and longer than the third coverage radius R3. For example, assuming a person with a height of 2 meters, coverage of 125 cm on the Z-axis, 100 cm on the Y-axis, and 75 cm on the X-axis is required.

Therefore, the coverage region of the magnetic field, generated by the transmitting coil in FIG. 8, needs to be formed so that the coverage region can cover the user's hand in the first state S1, where the user lowers the user's hand.

With reference to FIG. 8, transmitting coils (Tx Coils 1 to 4) may be placed near the front, rear, top, and sides of the head of the user wearing the HMD. In this regard, with reference to Table 1, there is a concern that excessive magnetic flux density at or above a threshold value may damage sensory organs such as the ears and the eyes. Symptoms of this damage may include nausea and vertigo, among others. It is advisable to avoid, to the greatest extent possible, the position P2 of Tx coil 2 and the position P4 of Tx coil 4, which may have an excessive effect on the eyes and the ears, because the magnetic flux density significantly affects the sensory organs. Therefore, the transmitting coil of the HMD according to the present disclosure may be placed at the position P1 of Tx coil 1 behind the user's head and the position P3 of Tx coil 3 over the head.

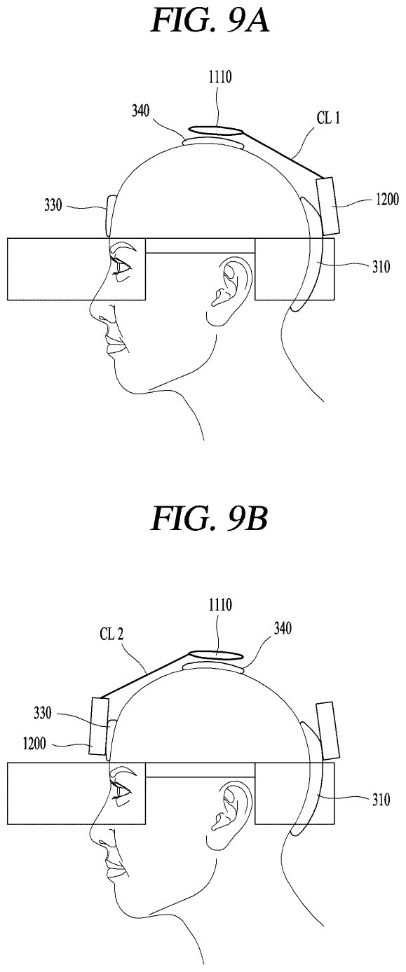

FIGS. 9A and 9B are views, each illustrating the configuration of the head-mounted display device according to the present disclosure, which includes the transmitting coil. FIG. 9A illustrates a structure in which the transmitting coil 1110 is placed over the user's head and a main board 1200 is placed behind the user's head. FIG. 9B illustrates a structure where the transmitting coil 1110 is placed over the user's head and the main board 1200 is placed in front of the user's head.

With reference to FIG. 9A, the transmitting coil 1110 may be placed over the user's head or at an inclined angle within a predetermined angular range relative to a horizontal direction above the user's head. The normal vector to the plane where the transmitting coil 1110 is placed may lie within a predetermined range of angles relative to a direction perpendicular to the user. The normal vector to the plane where the transmitting coil 1110 is placed may lie within a range of −20 degrees to +20 degrees relative to a direction perpendicular to the user. The main board 1200 may be placed behind the user's head. The main board 1200 may be placed on a rear support section 310 of the head-mounted display (HMD) device. One end of the transmitting coil 1110 may be connected via a first connection line CL1 to the main board 1200 placed on the rear support section 310. The transmitting coil 1110 may be placed on an upper support section 340 of the HMD device, thereby ensuring that the MPE-based separation distance is maintained between the transmitting coil 1110 and the user's head.

With reference to FIG. 9B, the transmitting coil 1110 may be placed over the user's head. The main board 1200 may be placed in front of the user's head. The main board 1200 may be placed on a front support section 330 of the head-mounted display (HMD) device. The other end of the transmitting coil 1110 may be connected via a second connection line CL2 to the main board 1200 placed on the front support section 330. The transmitting coil 1110 may be placed on the upper support section 340 of the HMD device, thereby ensuring that the MPE-based separation distance is maintained between the transmitting coil 1110 and the user's head.

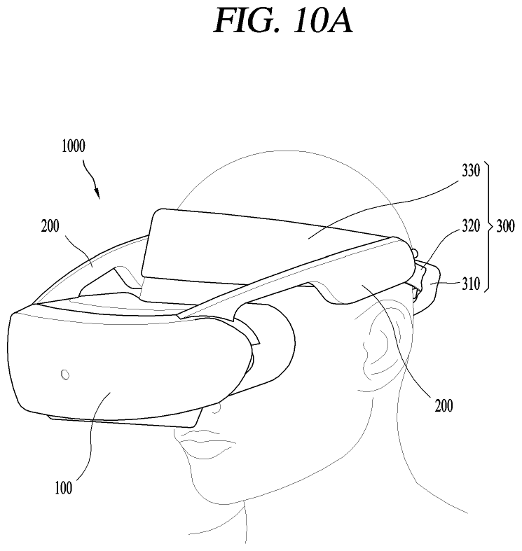

The head-mounted display (HMD) device according to the present disclosure, which includes the transmitting coil, may be configured to include a main body, a connection frame, and a fastening unit for wearing on the user's head. In this regard, FIGS. 10A and 10B are views, each illustrating the detailed structure of a head-mounted display device according to an embodiment.

FIG. 10A is a conceptual diagram illustrating a state in which a head-mounted display device 1000 according to an embodiment of the present disclosure is worn on the head. FIG. 10B is a conceptual diagram that is referenced to describe the state in which the HMD device moves and rotates the main body while being fastened to the user's head.

With reference to FIG. 10A, the head-mounted display (HMD) device 1000 may include: a main body 100 that includes display modules outputting an image; a connection frame 200 connected to the main body 100; a fastening unit 300 connected to the connection frame 200 and fastened to the head; and a band unit 400 that has elasticity and elastically supports the rear part of the head.

Assuming the front of the head is defined by the position of the user's eyes and the rear as the opposite side, the band unit 400 elastically supports the rear part of the head. The fastening unit 300 includes a rear support section 310, a connection section 320, and a front support section 330. The front support section 330 is fastened to the front part of the head. The rear support section 310 of the fastening unit 300 supports the rear part of the head while overlapping with the band unit 400.

The main body 100 is placed in front of the head by the fastening unit 300 and the band unit 400. The main body 100 is fastened to the connection frame 200. The connection frame 200 is configured to move in front of or behind the head relative to the fastening unit 300 or to rotate within a specific range of angles relative to the fastening unit 300. The user can approximately position the display modules in front of both of the user's eyes, respectively, by fastening the band unit 400 and the fastening unit 300 to the head and by moving and rotating the connection frame 200. Therefore, the user can primarily fasten the fastening unit using the band unit 400 and secondarily tighten the fastening unit to fit the head's size, thereby enabling more stable mounting of the head-mounted display unit 1000 to fit the head's size.

The HMD device is not limited to the configuration described above and may be varied and configured in various ways, with consideration of the components that can be mounted. The upper support section 340 in FIGS. 9A and 9B for placing the transmitting coil 1110 in FIGS. 9A and 9B in the HMD device may be integrated into the fastening unit 300 in FIG. 10A. As another example, the upper support section 340 in FIGS. 9A and 9B for placing the transmitting coil 1110 in FIGS. 9A and 9B in the HMD device may be implemented as the front support section 330 in FIG. 10A. In this regard, the front support section 330 may be extended to cover up to a region over the user's head. As another example, the front support section 330 may be placed in a region over a region over the HMD device and may be structurally formed to be rotatable across a region in front of the HMD device. Alternatively, the front support section 330 may be placed in a region in front of the HMD device and may be structurally formed to be rotatable across a region over the HMD device.

With reference to FIG. 10B, when an external force is applied unidirectionally to the main body 100, the main body 100 and the connection frame 200 move away from the fastening unit 300. That is, as the main body 100, which is mounted to closely contact the user's face, moves, a space is formed between the user's face and the main body 100. In this case, the user can wear glasses using the space. In addition, when an external force is again applied to the main body 100 in the opposite direction, the main body 100 may be placed to closely contact the user's face.

By applying an external force to the main body 100, the main body 100 may rotate about the region where the connection frame 200 and the fastening unit 300 are connected. When the main body 100 and the connection frame 200 rotate about one end of the connection frame 200, the main body 100 moves away from both of the user's eyes. The state in which the main body 100 is placed in alignment with the fastening unit 300 may be maintained.

The fastening unit 300 may be configured to further include the upper support section 340 so that the transmitting coil is placed in a region over the user's head. As another example, the front support section 330 of the fastening unit 300 may be extended to cover a region over the user's head. As another example, the front support section 330 may be placed in a region over the HMD device and may be structurally formed to be rotatable across a region in front of the HMD device. Alternatively, the front support section 330 may be placed in a region in front of the HMD device and may be structurally formed to be rotatable across a region over the HMD device.

Accordingly, when the user temporarily does not use the head-mounted display, the main body 100 may be moved away from both of the user's eyes and remain fixed in that position. Thus, the entire head-mounted display 1000 does not need to be separated from the head.

In addition, regardless of the position of the main body where the display unit is placed, the head-mounted display may be fastened to the head using the fastening unit 300 and the band unit 400. Thus, the head-mounted display may be first fastened to the head in a state where the view is not blocked by the main body.

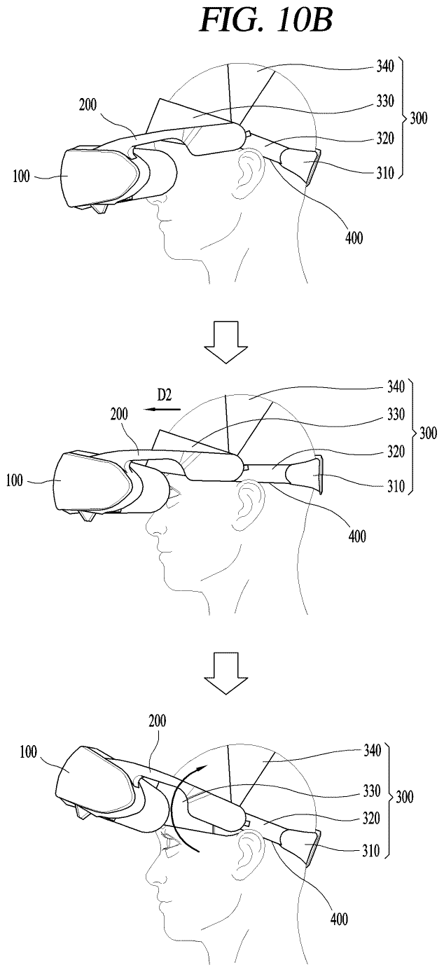

FIG. 11 is a view illustrating a structure in which a plurality of transmitting coils are placed at different positions relative to the user's head. With reference to FIG. 11, the transmitting coil 1110 may be placed in a region over the user's head. A second transmitting coil 1120 may be placed in a region behind the user's head. The magnetic flux of the transmitting coil 1110 may be generated in the vertical direction, with the user's head at the center. The magnetic flux of the second transmitting coil 1120 may also be generated in the vertical direction, with the user's head at the center/

The transmitting coil 1110 may be formed with a first height h1, which is low enough to be accommodated in the HMD device. To ensure the coverage radius of the three-dimensional spatial region of the magnetic field, the transmitting coil 1110 may be formed to have a first radius that is equal to or greater than a first threshold value. To be accommodated in the HMD device, the second transmitting coil 1120 may be formed to have a second radius that is equal to or smaller than a second threshold value. To ensure the coverage radius of the three-dimensional spatial region of the magnetic field, the second transmitting coil 1120 may be formed to have a second height h2 that is greater than the first height h1. The transmitting coil 1110 and the second transmitting coil 1120 are not limited to circular shapes and may be formed in arbitrary polygonal shapes, such as square, pentagonal, hexagonal, heptagonal, or octagonal shapes.

With reference to FIGS. 6 to 11, the head-mounted display device for estimating user interaction according to one aspect of the present disclosure is described. The head-mounted display device 1000 may be configured to include the main body 100, the transmitting coil 1110, and the main board 1200. The head-mounted display device 1000 may further include the rear support section 310 and the second transmitting coil 1120. The head-mounted display device 1000 constitutes a wireless power transmission device. The receiver 1500 worn on a part of the user's body or carried in the user's hand constitutes the wireless power receiving device.

The transmitting coil 1110 may be placed to face downward toward the user's head on which the main body 100 is worn. The transmitting coil 1110 may be configured in a circular shape with a number of turns to generate a magnetic field in a three-dimensional spatial region, with the user's head at the center.

The head-mounted display 1000 may be configured to include the main body 100, the connection frame 200 connected to the main body 100, the fastening unit 300 connected to the connection frame 200 and fastened to the head, and the band unit 400 that has elasticity and elastically supports the rear part of the head.

Assuming the front of the head is defined by the position of the user's eyes and the rear as the opposite side, the band unit 400 elastically supports the rear part of the head. The fastening unit 300 includes the rear support section 310, the connection section 320, and the front support section 330. The front support section 330 is fastened to the front part of the user's head. The rear support section 310 of the fastening unit 300 supports the rear part of the user's head while overlapping with the band unit 400.

The rear support section 310 may be formed to enclose the rear part of the user's head. The front support section 330 may be rotatably coupled to the connection frame 200. The front support section 330 may be placed to face downward toward the user's head. Accordingly, the transmitting coil 1110 may be placed on the front support section 330. The second transmitting coil 1120 may be placed on the rear support section 310. The second transmitting coil 1120 may be placed on the rear support section 310 in a manner that has a different shape than the transmitting coil 1110.

A first direction of a first magnetic flux generated by the transmitting coil 1110 and a second direction of a second magnetic flux generated by the second transmitting coil 1120 may be set to be the same. The first direction of the first magnetic flux generated by the transmitting coil 1110 and the second direction of the second magnetic flux generated by the second transmitting coil 1120 may be set to be a direction perpendicular to the user. The first direction of the first magnetic flux generated by the transmitting coil 1110 and the second direction of the second magnetic flux generated by the second transmitting coil 1120 may be set to be within a range of −20 degrees to +20 degrees relative to a direction perpendicular to the user.

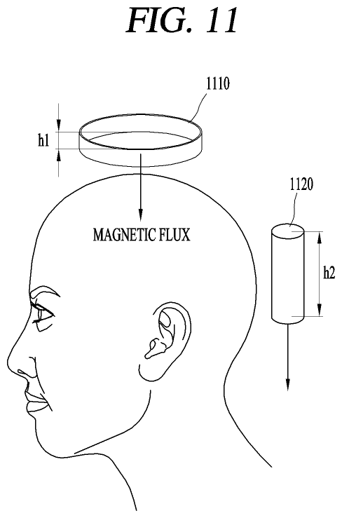

The main board 1200 may be operatively coupled to the transmitting coil 1110 and may be configured to transfer a signal to the transmitting coil 1110. The main board 1200 may be operatively coupled to the second transmitting coil 1120 and may be configured to transfer a signal to the second transmitting coil 1120. The three-dimensional spatial region generated by the transmitting coil 1110 may be determined based on the intensity of the magnetic field. In this regard, FIG. 12 is a view illustrating a comparison between the three-dimensional spatial regions in which the magnetic field is generated depending on the position of the transmitting coil.

With reference to (a) of FIG. 12, when the transmitting coil 1110 in a circular shape is placed over the user's head, the first coverage radius R1 may be set to be greater than the second coverage radius R2. With reference to FIG. 2 and FIGS. 6 to (a) of FIG. 12, the position and orientation of the receiver 1500 carried in the user's hand may be estimated by the magnetic field generated within the first coverage radius R1.

With reference to (b) of FIG. 12, when a second transmitting coil 1120b in a circular shape is placed in front of or behind the user's head, a first coverage radius R1b is set to be the same as a second coverage radius R2b. With reference to FIG. 2, FIGS. 6 to 11, and (b) of FIG. 12, the position and orientation of the receiver 1500 carried in the user's hand cannot be accurately measured due to the magnetic field generated within the first coverage radius R1b.

With reference to FIGS. 2, FIGS. 6 to 11, and (a) of FIG. 12, the three-dimensional spatial region may include the first coverage radius that is set in a vertical direction, with the user's head at the center. The three-dimensional spatial region may include the second coverage radius that extends horizontally, with the user's head at the center. The first coverage radius R1 within which the receiver 1500 is placed in a state where the user lowers the user's hand may be set to be greater than the second coverage radius R2 within which the receiver 1500 is placed in a state where the user raises the user's hand in a parallel direction.

The first coverage radius R1 refers to a radius within which a magnetic field can cover the position of the receiver in the first state S1 in which the user in FIG. 7A extends the user's hand forward. The first coverage radius R1 refers to a radius within which the magnetic field region can provide coverage along one axis in a direction horizontal to the user in (a) of FIG. 12. The second coverage radius R2 refers to a radius within which the magnetic field can cover the position of the receiver in the second state S2 where the user in FIG. 7a raises the user's arm parallel to the ground. The second coverage radius R2 refers to a radius within which the magnetic field area can provide coverage along the other axis in a direction perpendicular to the user in (a) of FIG. 12.

The three-dimensional spatial region may be configured to further include the third coverage radius R3 that is set to extend forward and backward, with the user's head at the center. The third coverage radius R3 refers to a radius within which the magnetic field can cover the position of the receiver in the third state S3 where the user in FIG. 7B extends the user's hand forward. The third coverage radius R3 within which the receiver is placed in a state where the user's hand is extended forward may be set to be smaller than the second coverage radius R2.

With reference to FIGS. 6 to 11, the transmitting coil 1110 may be formed by winding a coil in a circular shape with the first radius, up to the first height h1 in the vertical direction, so that the coil has a first number of turns. The second transmitting coil 1120 may be formed by winding a coil in a circular shape with the second radius smaller than the first radius, up to the second height h2 in the vertical direction, so that the coil has a second number of turns that is greater than the first number of turns. The second height h2 of the second transmitting coil 1120 may be set to be greater than the first height h1 of the transmitting coil 1110. The second transmitting coil 1120 is placed behind the user's head. Therefore, even when formed to have a higher height than the transmitting coil 1110, the second transmitting coil 1120 may be accommodated in the rear support section of the head-mounted display device. Thus, the second transmitting coil 1120 may be implemented to have a small thickness.

The first radius of the transmitting coil 1110 may be set to be greater than or equal to 28 mm and less than or equal to 39 mm. The first number of turns of the transmitting coil 1110 may be set to be greater than or equal to 200 and less than or equal to 300. In a case where the first radius of the transmitting coil 1110 is 28 mm and the first number of turns of the transmitting coil 1110 is 300, the distance between the lower end of the transmitting coil 1110 and the top of the head may be set to 4.5 cm or more. In a case where the first radius of the transmitting coil 1110 is 39 mm and the first number of turns of the transmitting coil 1110 is 200, the distance between the lower end of the transmitting coil 1110 and the top of the head may be set to 3.4 cm or more.

In this regard, Table 1 shows the specifications of a transmitting coil according to an embodiment of the present specification. With reference to Table 1, the maximum coverage of the transmitting coil in Case 1 is set to approximately 140 cm to cover the first coverage radius, and the transmitting coil exhibits a magnetic field strength of 10.7 nT or more. The number of turns of the transmitting coil in Case 1 is set to 200, and a current of 300 mA may flow through the coil. The radius of the transmitting coil in Case 1 is set to 28 mm, and the area thereof may be set to approximately 2463 mm². The separation distance of the transmitting coil in Case 1 may be determined to be approximately 4.5 cm based on the maximum power exposure (MPE).

TABLE 1

| | |
|---|---|
| Case 1 | Case 2 |

| | | |
|---|---|---|
| Max Coverage | 140 cm (10.7 nT) | 140 cm (10.4 nT) |
| N (the number of turns) | 200 | 200 |

| | | | | |
|---|---|---|---|---|
| Current | 300 | mA | 150 | mA |
| Radius | 28 | mm | 39 | mm |
| Area | 2463 | mm² | 4778 | mm² |
| Separation Distance | 4.5 | cm | 3.4 | cm |
| (MPE) | | | | |

The maximum coverage of the transmitting coil in Case 2 is set to approximately 140 cm to cover the first coverage radius, and the transmitting coil exhibits a magnetic field strength of 10.4 nT or more. The number of turns of the transmitting coil in Case 2 is set to 200, and a current of 150 mA may flow through the coil. The radius of the transmitting coil in Case 1 is set to 39 mm, and the area thereof may be set to approximately 4778 mm². The separation distance of the transmitting coil in Case 2 may be determined to be approximately 3.4 cm based on the MPE. The transmitting coil 1110 and the second transmitting coil 1120 may be formed as single-axis coils to face downward toward the user's head so that the magnetic flux is generated in a direction perpendicular to the user's head. In this regard, the transmitting coil 1110 and the second transmitting coil 1120 may be single-axis coils that form magnetic flux in the Z-axis direction perpendicular to the user's head. The receiver may include a receiving coil formed by a three-axis coil to detect the position and orientation of the user's hand holding the receiver.

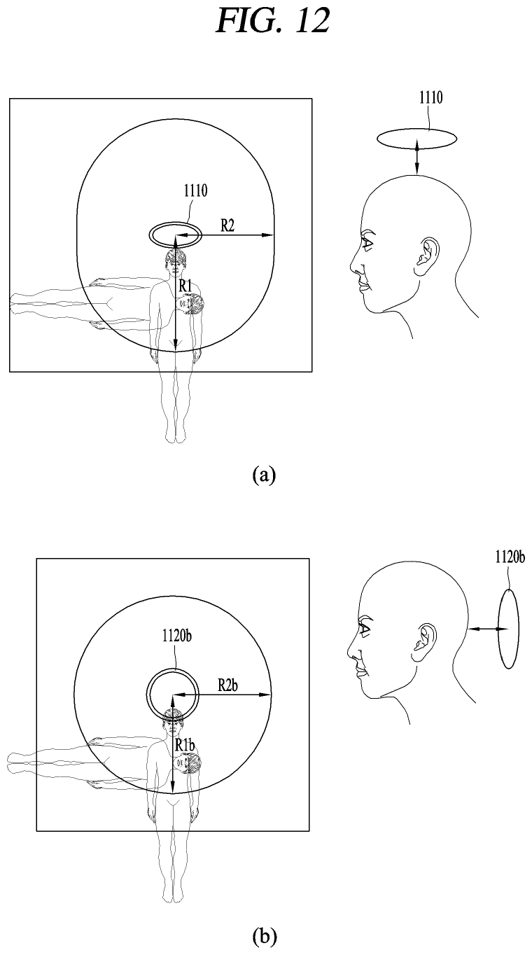

As another embodiment, the transmitting coil forms a magnetic field whose coverage radius varies based on changes in the number of turns and the radius, while the current of the transmitting coil is kept constant. This coverage radius is described. In this regard, Table 2 shows the specifications of the transmitting coil according to an embodiment of the present disclosure. FIG. 13 is a set of views illustrating the coverage radii of the magnetic fields generated by the transmitting coil in Table 2, shown in the form of different cross-sectional views.

TABLE 2

| | Case 1 |
|---|---|
| N (the number of turns) | 200 to 300 |
| Thickness | 6 to 10 mm |
| Current | 150 mA |
| Radius | 32 mm to 39 mm |
| MPE distance | 34 mm to 40 mm |

Table 2 shows the MPE-based separation distance of the transmitting coil, which varies based on changes in the number of turns and the radius while the current of the transmitting coil is kept constant. With reference to Table 2 and FIG. 13, the number of turns of the transmitting coil 1110 may be set in the range of 200 to 300. The total thickness, which is the product of the unit thickness of the transmitting coil 1110 and the number of turns, may be set in the range of 6 to 10 mm. While maintaining the current flowing through the transmitting coil 1110 at a constant 150 mA, the radius of the transmitting coil 1110 may be set in the range of 32 mm to 39 mm. Accordingly, the separation distance from the top of the head to the transmitting coil 1110, based on MPE, may be set in the range of approximately 34 mm to 40 mm. With reference to FIG. 7A and (a) of FIG. 13, the first coverage radius of the transmitting coil 1110 may be set to 143 cm. Therefore, it is possible to estimate the position and orientation of the hand even in a state where a person approximately 2 meters tall lowers the user's hand while the receiver is held in it. With reference to FIG. 7B and (b) of FIG. 13, the third coverage radius of the transmitting coil 1110 may be set to 102 cm. Therefore, it is possible to estimate the position and orientation of the hand even in a state where a person approximately 2 meters tall extends the user's hand forward while the receiver is held in it.

Compared to the case where the current flowing through the transmitting coil in Case 1 in Table 1 is set to 300 mA, the separation distance may be reduced to 40 mm or less by decreasing the current flowing through the transmitting coil in Table 2 to 150 mA, even when the number of turns and the radius of the coil are increased. Accordingly, the separation distance from the top of the user's head may be reduced while increasing the radius and thickness of the transmitting coil. Therefore, the coverage for estimating the user interaction may be maintained or increased while reducing the overall height of the HMD device.

From the perspective of a usage scenario and body proportions in FIGS. 7A and 7B, it is necessary that the second transmitting coil 1120b in a circular shape behind the head in (b) of FIG. 12 has a larger radius and/or a greater number of turns than the transmitting coil 1110 in a circular shape over the head in (a) of FIG. 12. In the second transmitting coil 1120b, which is placed behind the head, the magnetic flux density is insufficient, resulting in a decrease in the coverage radius R1b compared to the first coverage radius R1 that can cover the user's hand. Therefore, it is necessary to increase the radius and/or the number of turns of the second transmitting coil 1120b in order to achieve the same coverage radius as the first coverage radius R1 of the transmitting coil 1110. For example, the diameter of the transmitting coil 1110 and the second transmitting coil 1120b for the same coverage may be determined to be 78 mm and 94 mm, respectively. When the second transmitting coil 1120b is placed behind the user's head or in front of the eyeball, the size of the second transmitting coil 1120b must be increased to estimate the user interaction. The separation distance between the coil and the body based on the MPE is determined to be 34 mm for the transmitting coil 1110, whereas it is determined to be 53 mm for the second transmitting coil 1120b.

Furthermore, the transmitting coil 1110 in a circular shape placed over the head in (a) of FIG. 12 may acquire magnetic flux density values through coupling to the receiving coil and the sensors, thereby enabling positioning estimation with an error margin of 1 mm or less. Additionally, the receiving coil is implemented as a three-axis coil and is coupled to the sensors, thereby enabling six degrees of freedom (DoF) control.

A main board 1300 of the head-mounted display device 1000 for estimating user interaction according to the present disclosure, which possesses these positioning estimation capabilities, may be configured to include a processor. With reference to FIGS. 2 and FIGS. 6 to 13, the processor of the main board 1300 may be configured to estimate the position and orientation of the receiver 1500 with respect to the transmitting coil 1110. The processor of the main board 1300 may be configured to estimate the position and orientation of the receiver 1500 with respect to the second transmitting coil 1120. As another embodiment, the receiver 1500 may also be configured to estimate its own position and orientation in conjunction with the main board 1300.

Since the head-mounted display device 1000 includes a plurality of transmitting coils, the positions and orientations of the receivers may be estimated more accurately. In addition, in a case where the ability to estimate the positions and orientations of receivers using one transmitting coil is diminished, the positions and orientations of the receivers may also be estimated using another transmitting coil. In order to enhance these complementary capabilities, the transmitting coil 1110 and the second transmitting coil 1120 may use different times and/or frequency resources. Accordingly, the transmitting coil 1110 and the second transmitting coil 1120 may be configured to generate magnetic fields at first and second frequencies, different from each other, and to transmit a first signal and a second signal, respectively.

The processor may estimate the position and orientation of the receiver 1500 from the first signal at the first frequency, which is transmitted from the transmitting coil 1110. When the location and orientation of the receiver 1500 are not estimated, or estimation performance is determined to be below a threshold value, the second transmitting coil 1120, which is formed in a different shape at a different location than the transmitting coil 1110, may be used. The processor may estimate the position and orientation of the receiver 1500 from the second signal at the second frequency, which is transmitted from the second transmitting coil 1120.

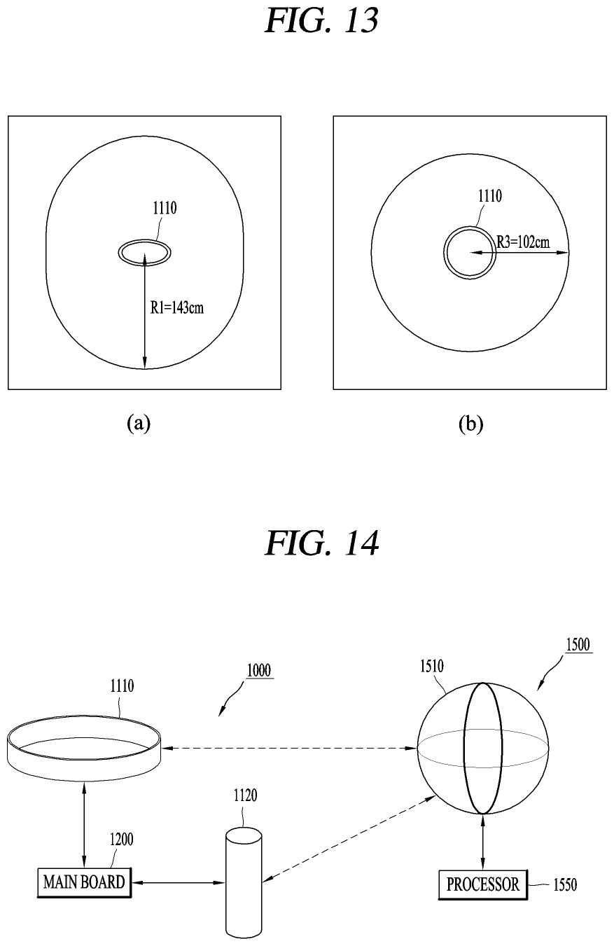

The head-mounted display device including the transmitting coil for estimating the user interaction according to one aspect of the present specification is described above. The system for estimating user interaction according to another aspect of the present disclosure is described above. In this regard, FIG. 14 is a block diagram illustrating the system for estimating user interaction according to the present disclosure.

With reference to FIGS. 1 to 14, the system for estimating user interaction may be configured to include the head-mounted display device 1000 and the receiver 1500. The head-mounted display device 1000 is configured to form the three-dimensional spatial region of the magnetic field through at least one transmitting coil 1110. The receiver 1500 may include the receiving coils 1510, 1520, and 1530, which are placed within the three-dimensional spatial region and configured to receive the magnetic field generated by the transmitting coil 1110.

The head-mounted display device 1000 may include the main body 100 including the display unit that outputs an image. The head-mounted display device 1000 may include the transmitting coil 1110 placed to face downward forward the head of the user wearing the main body 1000. The transmitting coil 1110 may be configured in a circular shape with a number of turns to generate the magnetic field in the three-dimensional spatial region, with the user's head at the center. The head-mounted display device 1000 may include the main board 1200 that is operatively coupled to the transmitting coil 1110 and configured to transfer a signal to the transmitting coil 1110.

The three-dimensional spatial region where the magnetic field is generated may be determined based on the intensity of the magnetic field. The three-dimensional spatial region may include the first coverage radius R1 that extends in the vertical direction, with the user's head at the center. The three-dimensional spatial region may include the second coverage radius R2 that extends horizontally three-dimensional spatial region, with the user's head at the center. The first coverage radius R1 within which the receiver 1500 is placed in the state where the user lowers the user's hand may be set to be greater than the second coverage radius R2 within which the receiver 1500 is placed in the state where the user raises the user's hand in the parallel direction.

The head-mounted display device 1000 may include the rear support section 310 that is formed to enclose the rear part of the user's head. The head-mounted display device 1000 may include the second transmitting coil 1120 placed in a different shape on the rear support section 310 than the transmitting coil 1110. The first direction of the first magnetic flux generated by the transmitting coil 1110 and the second direction of the second magnetic flux generated by the second transmitting coil 1120 may be set to be within a range of −20 degrees to +20 degrees relative to a direction perpendicular to the user.

The transmitting coil 1110 may be formed by winding a coil in a circular shape with the first radius, up to the first height h1 in the vertical direction, so that the coil has the first number of turns. The second transmitting coil 1120 may be formed by winding a coil in a circular shape with the second radius smaller than the first radius, up to the second height h2 in the vertical direction, so that the coil has the second number of turns that is greater than the first number of turns. The second transmitting coil 1120 may be formed in such a manner that the second height h2 thereof is greater than the first height h1 of the transmitting coil 1110.

The first radius of the transmitting coil 1110 may be set to be greater than or equal to 28 mm and less than or equal to 39 mm. The first number of turns of the transmitting coil 1110 may be set to be greater than or equal to 200 and less than or equal to 300. In the case where the first radius of the transmitting coil 1110 is 28 mm and the first number of turns of the transmitting coil 1110 is 300, the distance between the lower end of the transmitting coil 1110 and the top of the head may be set to 4.5 cm or more. In the case where the first radius of the transmitting coil 1110 is 39 mm and the first number of turns of the transmitting coil 1110 is 200, the distance between the lower end of the transmitting coil 1110 and the top of the head may be set to 3.4 cm or more.

The transmitting coil 1110 and the second transmitting coil 1120 may be formed as single-axis coils to face downward forward the user's head so that the magnetic flux is generated in a direction perpendicular to the user's head. The receiving coils 1510, 1520, and 1530 may be configured as three-axis coils to detect the position and orientation of the hand of the user holding the receiver 1500.

The receiver 1500 may further include a processor configured to estimate the position and orientation of the receiver 1500 relative to the transmitting coil 1110. A processor 1550 of the receiver 1500 may estimate the position and orientation of the receiver 1500 from the first signal at the first frequency, which is transmitted from the transmitting coil 1110. When the position and orientation of the receiver are not estimated, the processor 1550 of the receiver 1500 may estimate the position and orientation of the receiver 1500 from the second signal at the second frequency, which is transmitted from the second transmitting coil 1120.

As described, the head-mounted display device according to the present disclosure includes the transmitting coil that employs the positioning method based on the near-field magnetic field. The technical features of this device and the system for user interaction are summarized as follows.

1) A frequency of approximately 32 kHz may be selected as the operating frequency of the transmitting coil for near-field-based positioning estimation. Although an operating frequency of approximately 131 kHz may be selected for the transmitting coil, an operating frequency of approximately 32 kHz may be selected with consideration of the coverage region. A characteristic of this operating frequency is low current consumption in relation to induced current and voltage. Thus, selecting a lower operating frequency makes it possible to ensure the coverage region at or above a predetermined level, even under low current conditions. The transmitting coil, which operates at an approximate frequency of 32 kHz, may be implemented to have a small radius and a small number of turns. Thus, the transmitting coil may be implemented to have a compact size and a low height in the head-mounted display device. In addition, from the perspective of low instantaneous power and radiated field, it is desirable to select a lower frequency for the operating frequency of the transmitting coil.

2) The receiving coils that are implemented as three-axis coils may be formed to enclose the structure of an internal mechanism that accommodates components of the receiver (receiving device). In this regard, the receiver (receiving device) is not worn on the user's head, but is instead carried in the user's hand or attached to the user's wrist, ankle, or other parts of the body. Therefore, even when the receiving coils are implemented as three-axis coils, they may be formed to encircle the body of the internal mechanism and may be accommodated within an external mechanism of the receiving device.

3) For a calibration setup estimating the user interaction, calibration may be conducted not only between the head-mounted display device, which corresponds to the transmitting device, and the receivers, but also among the receivers themselves. The correlation with measured sensing values between specific positions may be used. The specific positions vary depending on the motion of the user's hand or other body parts within the coverage radius of the three-dimensional spatial region of an asymmetric magnetic field generated by the transmitting coil implemented as a single-axis coil. Accordingly, the transmitting device and/or receiver may estimate the exact position and orientation based on the approximate position and orientation estimated from the sensor.

4) After calibration, the position and orientation may be estimated depending on the motion of the user's hand and other body parts, with consideration of various real-world usage environmental conditions. For example, the position and orientation may be estimated based on the environmental conditions (e.g., temperature and humidity) of the spatial area where the positioning of the user is estimated and on the type of, and detailed information about, an application program being executed by the user.

5) Component placement may be designed with consideration of the positions at which the transmitting coil and the receiving coil are placed. For example, the transmitting coil may be placed in a region over and/or behind the head, and the receiving coil may be placed on the user's hand, wrist, ankle, or other body parts. For example, the position of the main board of the transmitting device and a board where the processor of the receiver is placed may be determined by the distance and interface between the components.

6) When magnetization occurs in the areas surrounding the transmitting coil and the receiving coil, a signal is prevented from being applied from the main board to the transmitting coil. Accordingly, a mechanism for preventing magnetization may be implemented. In addition, while an application for estimating the user interaction is executed, if the degree of magnetization due to the magnetization phenomenon is at or below a threshold value, then for accurate user interaction estimation, a signal must be continuously applied to the transmitting coil, or another transmitting coil must be used. Alternatively, the transmitting coil may be controlled to operate at a different frequency to alleviate the magnetization phenomenon.

7) Signal blocking, signal path switching to another transmitting coil, and/or a change in operating frequency may be performed with consideration of the magnetic field interference effect between the transmitting coil and the receiving coils or between the boards of the transmitting device and the receiver.

8) A method of correcting estimation errors in position and orientation using data from various sensors (such as a gyroscope sensor, an accelerometer sensor, a geomagnetic sensor, and a coil) may be performed. In addition, inter-data synchronization and adjustment of data resolution are necessary for correcting these estimation errors.

9) To miniaturize the coil, a core made of soft magnetic materials such as ferrite may be used.

9) During integration for application to actual devices, it is necessary to analyze the impact of ferromagnetic substances, such as iron, nickel, and cobalt, on the magnetic field for a product family of the systems for estimating, each including the transmitting device and the receiver.

10) It is necessary to analyze the distance estimation between the transmitting device and the receiver with consideration of the magnetic flux density in the near field and the nonlinearity of the intensity of the magnetic field.

11) It is necessary to analyze issues related to the application of products that arise due to maximum permissible exposure (MPE). Accordingly, the positions at which the transmitting coils can be placed, the structures of the coils, the design of a cushion in which the coils are embedded, and the like may be configured in the head-mounted display device.

12) It is necessary to analyze the impact on the human body when wearing the head-mounted display (HMD) device, with consideration of the transmitting coils with specific shapes and structures and the regions in which they are placed.

13) It is necessary to analyze the causes of the occurrence of the estimation errors in position and orientation for estimating the user interaction and to propose improvements for eliminating these causes. As described above, the transmitting coil in a circular shape, which is placed over the user's head, operates in conjunction with the receiving coil and the sensors and thus acquires magnetic flux density values, thereby enabling positioning estimation with an error margin of 1 mm or less. In addition, the receiving coil is implemented as a three-axis coil and is coupled to the sensors, thereby enabling six degrees of freedom (DoF) control.

The above-described embodiments are associated not only with the head-mounted display device, in which the transmitting device including the transmitting coil is implemented, and the system for estimating user interaction, which includes the head-mounted display device, but also with the control operations of the head-mounted display device and the system for estimating user interaction. Various alterations and modifications to these embodiments would be clearly understood by a person of ordinary skill in the art without departing from the spirit and scope of the underlying technical idea of the present disclosure. Therefore, it should be understood that these various modifications and alterations fall within the scope of the present disclosure that are defined in the following claims.

The head-mounted display device, in which the transmitting device including the transmitting coil is implemented, and the system for estimating user interaction, which includes the head-mounted display device, are described above. The technical effects of the head-mounted display device, in which the transmitting device including the transmitting coil is implemented, and the technical effects of the system for estimating user interaction, which includes the head-mounted display device, are described as follows.

According to the present disclosure, the transmitting device including the transmitting coil may be implemented in the head-mounted display device. In addition, the system for estimating user interaction may be provided that includes the transmitting device, including the transmitting coil, and the receiving device, including the receiving coil.

According to the present disclosure, in a case where the transmitting coil is implemented as a single-axis coil, it is possible to design the shape and placement structure of the transmitting coil, which result from taking into consideration the three-dimensional spatial area and the coverage radius along three axes, which are formed by the magnetic field generated by the transmitting coil. It is possible to accurately estimate the user's motion by analyzing the three-dimensional spatial region and the coverage radius along the three axes, which is formed by the magnetic field resulting from taking into consideration the shape and placement of the transmitting coil.

According to the present disclosure, using the HMD device, it is possible to analyze the minimum separation distance between the coil and the user's head, based on the appropriate level of maximum power exposure (MPE), with consideration of the impact on human health. Particularly, it is possible to accurately estimate the user's motion through the analysis of the minimum separation distance between the coil and the user's head, based on the MPE of the magnetic field generated according to the shape and placement structure of the transmitting coil.

According to the present disclosure, it is possible to ensure sufficient coverage of the magnetic field generated by the coil, based on the coil placement resulting from taking into consideration the minimum separation distance between the coil and the user's head and on the current applied to the coil.

According to the present disclosure, it is possible to design the shape and placement structure of the transmitting coil, which results from taking into consideration a design element of a commercial wearable device, in a magnetic field-based system for estimating user interaction. In the commercial wearable device, an MPE-based separation distance should be minimized.

According to the present disclosure, which is described above, the control operation of the head-mounted display device including the transmitting coil for estimating user interaction and the control operation of the system for estimating user interaction may be performed in software, firmware or a combination of both. A constituent element that performs control of the wireless power transmission device, including a plurality of transmitting coils and a shielding coil, and control of a wireless power transfer system, including the wireless power transmission device, is implemented as computer-readable code on a program-recorded medium.

Computer-readable mediums include all types of recording devices on which data readable by a computer system are stored. Furthermore, examples of the computer-readable medium include a hard disk drive (HDD), a solid-state disk (SSD), a silicon disk drive (SDD), a ROM, a RAM, a CD-ROM, a magnetic tape, a floppy disk, an optical data storage device, and similar storage devices. The computer-readable medium may also be realized in the form of a carrier wave (such as for transmission over the Internet). In addition, the computer may include a controller of a terminal or a vehicle, namely, a processor. Therefore, the description detailed above should be regarded as exemplary, without being interpreted in a limited manner in all aspects. The scope of the present disclosure should be determined by the proper construction of the following claims. All equivalent modifications to the embodiments of the present disclosure are intended to fall within the scope of the present disclosure.

1. A head-mounted display device comprising:
a main body that includes a display unit outputting an image;
a transmitting coil that is placed to face downward toward a user's head, on which the main body is worn, and is configured in a circular shape with a number of turns to form a magnetic field in a three-dimensional spatial region, with the user's head at the center; and
a main board that is operatively coupled to the transmitting coil and is configured to transfer a signal to the transmitting coil,
wherein the three-dimensional spatial region where the magnetic field is generated is determined based on the intensity of the magnetic field,
wherein the three-dimensional spatial region comprises:
a first coverage radius that is set in a vertical direction, with the user's head at the center; and
a second coverage radius that is set in a horizontal direction, with the user's head at the center, and
wherein the first coverage radius within which a receiver is placed in a state where the user lowers the user's hand is set to be greater than the second coverage radius within which the receiver is placed in a state where the user raises the user's hand in the horizontal direction.

2. The head-mounted display device of claim 1, wherein the three-dimensional spatial region further comprises:
a third coverage radius that is set to extend forward and backward, with the user's head at the center, and
wherein the third coverage radius within which the receiver is placed in a state where the user's hand is extended forward is set to be smaller than the second coverage radius.

3. The head-mounted display device of claim 1, further comprising:
a rear support section formed to enclose the rear part of the user's head; and
a second transmitting coil placed on the rear support section in a manner that has a different shape than the transmitting coil.

4. The head-mounted display device of claim 3, wherein a first direction of a first magnetic flux generated by the transmitting coil and a second direction of a second magnetic flux generated by the second transmitting coil are set to be within a range of −20 degrees to +20 degrees relative to a direction perpendicular to the user.

5. The head-mounted display device of claim 3, wherein the transmitting coil is formed by winding a coil in a circular shape with a first radius, up to a first height in the vertical direction, so that the coil has a first number of turns.

6. The head-mounted display device of claim 5, wherein the second transmitting coil is formed by winding a coil in a circular shape with a second radius smaller than the first radius, up to a second height in the vertical direction, so that the coil has a second number of turns that is greater than the first number of turns, and
wherein the second height is set to be greater than the first height.

7. The head-mounted display device of claim 6, wherein
the first radius is greater than or equal to 28 mm and less than or equal to 39 mm.

8. The head-mounted display device of claim 7, wherein the first number of turns of the transmitting coil is greater than or equal to 200 and less than or equal to 300.

9. The head-mounted display device of claim 8, wherein in a case where the first radius of the transmitting coil is 28 mm and the first number of turns of the transmitting coil is 300, the distance between the lower end of the transmitting coil and the top of the head is set to 4.5 cm or more, and
wherein in a case where the second radius of the transmitting coil is 39 mm and the first number of turns of the transmitting coil is 200, the distance between the lower end of the transmitting coil and the top of the head is set to 3.4 cm or more.

10. The head-mounted display device of claim 3, wherein the transmitting coil and the second transmitting coil are formed as single-axis coils to face downward toward the user's head so that magnetic flux is generated in a direction perpendicular to the user's head, and
wherein the receiver comprises:
a receiving coil formed as a three-axis coil to detect the position and orientation of the user's hand holding the receiver.

11. The head-mounted display device of claim 10, wherein the main board includes a processor configured to estimate the position and orientation of the receiver with respect to the transmitting coil.

12. The head-mounted display device of claim 11, wherein the transmitting coil and the second transmitting coil are configured to generate magnetic fields at first and second frequencies, different from each other, and to transmit a first signal and a second signal, respectively,
wherein the processor estimates the position and orientation of the receiver from the first signal at the first frequency, transmitted from the transmitting coil, and
wherein when the position and orientation of the receiver are not estimated, the processor estimates the position and orientation of the receiver from the second signal at the second frequency, transmitted from the second transmitting coil.

13. A system for estimating user interaction, the system comprising:
a head-mounted display device that forms a three-dimensional spatial region of a magnetic field through at least one transmitting coil; and
a receiver that includes a receiving coil that is placed within the three-dimensional spatial region and is configured to receive the magnetic field generated by the transmitting coil,
wherein head-mounted display device comprises:
a main body that includes a display unit outputting an image;
a transmitting coil that is placed to face downward toward a user's head, on which the main body is worn, and is configured in a circular shape with a number of turns to form a magnetic field in a three-dimensional spatial region, with the user's head at the center; and
a main board that is operatively coupled to the transmitting coil and is configured to transfer a signal to the transmitting coil,
wherein the three-dimensional spatial region where the magnetic field is generated is determined based on the intensity of the magnetic field,
wherein the three-dimensional spatial region comprises:
a first coverage radius that is set in a vertical direction, with the user's head at the center; and
a second coverage radius that is set in a horizontal direction, with the user's head at the center, and
wherein the first coverage radius within which a receiver is placed in a state where the user lowers the user's hand is set to be greater than the second coverage radius within which the receiver is placed in a state where the user raises the user's hand in the horizontal direction.

14. The system of claim 13, wherein the head-mounted display apparatus further comprises:
a rear support section formed to enclose the rear part of the user's head; and
a second transmitting coil placed on the rear support section in a manner that has a different shape than the transmitting coil,
wherein a first direction of a first magnetic flux generated by the transmitting coil and a second direction of a second magnetic flux generated by the second transmitting coil are set to be within a range of −20 degrees to +20 degrees relative to a direction perpendicular to the user.

15. The system of claim 14, wherein the transmitting coil is formed by winding a coil in a circular shape with a first radius, up to a first height in the vertical direction, so that the coil has a first number of turns,
wherein the second transmitting coil is formed by winding a coil in a circular shape with a second radius smaller than the first radius, up to a second height in the vertical direction, so that the coil has a second number of turns that is greater than the first number of turns, and
wherein the second height is set to be greater than the first height.

16. The system of claim 15, wherein the first radius is greater than or equal to 28 mm and less than or equal to 39 mm, and
wherein the first number of turns of the transmitting coil is greater than or equal to 200 and less than or equal to 300.

17. The system of claim 16, wherein in a case where the first radius of the transmitting coil is 28 mm and the first number of turns of the transmitting coil is 300, the distance between the lower end of the transmitting coil and the top of the head is set to 4.5 cm or more, and
wherein in a case where the second radius of the transmitting coil is 39 mm and the first number of turns of the transmitting coil is 200, the distance between the lower end of the transmitting coil and the top of the head is set to 3.4 cm or more.

18. The system of claim 14, wherein the transmitting coil and the second transmitting coil are formed as single-axis coils to face downward toward the user's head so that magnetic flux is generated in a direction perpendicular to the user's head, and
wherein the receiver comprises:
the receiver comprises:
a receiving coil formed as a three-axis coil to detect the position and orientation of the user's hand holding the receiver.

19. The system of claim 18, wherein the receiver further comprises:
a processor configured to estimate the position and orientation of the receiver with respect to the transmitting coil.

20. The system of claim 19, wherein the transmitting coil and the second transmitting coil are configured to generate magnetic fields at first and second frequencies, different from each other, and to transmit a first signal and a second signal, respectively,
wherein the processor estimates the position and orientation of the receiver from the first signal at the first frequency, transmitted from the transmitting coil, and
wherein when the position and orientation of the receiver are not estimated, the processor estimates the position and orientation of the receiver from the second signal at the second frequency, transmitted from the second transmitting coil.
